(19) United States
(12) Patent Application Publication
(10) Pub. No.: US 2026/0362607 A1
(43) Pub. Date: Nov. 12, 2026

(54) VISCOUS FLUID SUPPLY DEVICE AND CARTRIDGE

(71) Applicant: FUJI CORPORATION, Chiryu (JP)

(72) Inventors: Shoji FUKAKUSA, Yokkaichi-shi (JP); Tsutomu TAKAHASHI, Toyohashi-shi (JP); Takeo HIRAI, Nagoya-shi (JP)

(73) Assignee: FUJI CORPORATION, Chiryu (JP)

(21) Appl. No.: 19/490,627

(22) PCT Filed: Aug. 1, 2023
(86) PCT No.: PCT/JP2023/028137

§ 371 Date: Dec. 5, 2025

(51) Int. Cl. H05K 3/3485

(52) U.S. Cl. CPC H05K 3/3485

(57) ABSTRACT

A viscous fluid supply device supplies viscous fluid used for printing. The viscous fluid supply device includes a holder including an opening through which a cartridge accommodating the viscous fluid is insertable and removable, and a mounting-receiving section on which the cartridge is mounted by pressing the cartridge rearward in a horizontal direction from the opening, and a first air supply section provided on the mounting-receiving section such that the first air supply section is connected to the cartridge in a state where the cartridge is mounted on the mounting-receiving section, and configured to supply first air to the cartridge for discharging the viscous fluid from the cartridge.

### TECHNICAL FIELD

The present description discloses a viscous fluid supply device and a cartridge.

### BACKGROUND ART

In the related art, a printing machine that prints solder as viscous fluid on a board using a screen mask has been proposed, the printing machine including a supply head that supplies the solder accommodated in a cartridge onto the screen mask (for example, see Patent Literature 1). The supply head includes a cylindrical air supply section connected to a hole provided in an upper portion of the cartridge to supply air, and a hollow disk-shaped clamp section fitted to a bottom portion of the cartridge to fix the cartridge in a state where the air supply section is connected to the cartridge. The cartridge includes a cylindrical main body section (housing), an accommodation container (cup) that accommodates the solder, and a lid member that is fitted into an opening of the accommodation container and has a nozzle (discharge port) formed at the center. The cartridge discharges the solder from the nozzle by relatively moving the accommodation container and the lid member using a pressure of the air supplied from the air supply section to the main body section and pushing the lid member into the accommodation container.

### CITATION LIST

### Patent Literature

Patent Literature 1: WO2017/006382A

### BRIEF SUMMARY

### Technical Problem

In the device described in Patent Literature 1, after the hole in the upper portion of the cartridge is inserted into the cylindrical air supply section, the hollow disk-shaped clamp section is rotated to fit and fix the clamp section to the bottom portion of the cartridge. Therefore, the structure becomes complicated, and it takes time and effort to attach and detach the cartridge.

An object of the present disclosure is to further facilitate the attachment and detachment of the cartridge.

### Solution to Problem

The present disclosure adopts the following means to achieve the above-described object.

The present disclosure relates to a viscous fluid supply device to be mounted in a printing machine, the viscous fluid supply device being for supplying viscous fluid used for printing, the viscous fluid supply device including:
a holder including an opening through which a cartridge accommodating the viscous fluid is insertable and removable, and a mounting-receiving section on which the cartridge is mounted by pressing the cartridge rearward in a horizontal direction from the opening; and
a first air supply section provided on the mounting-receiving section such that the first air supply section is connected to the cartridge in a state where the cartridge is mounted on the mounting-receiving section, and configured to supply first air to the cartridge for discharging the viscous fluid from the cartridge.

In the viscous fluid supply device of the present disclosure, the cartridge can be mounted to the holder and the first air supply section can be connected to the cartridge at the same time simply by pressing the cartridge rearward in the horizontal direction from the opening. As a result, the attachment and detachment of the cartridge can be further facilitated.

The present disclosure relates to a cartridge to be detachably attached to a printing machine, the cartridge being for accommodating viscous fluid used for printing, the cartridge including:
a bottomed cylindrical cup configured to accommodate the viscous fluid;
a sliding member provided to be slidable on an inner peripheral surface of the cup and having a discharge port; and
a housing that is a member configured to accommodate the cup and the sliding member with a gap on an inner peripheral side, and has an air inlet for introducing air for discharging the viscous fluid in the cup from the discharge port, wherein the air inlet is provided on a side surface of the housing, identification information readable by a reader is provided on a bottom surface of the cup, and at least a portion of the housing corresponding to the identification information is formed of a transparent member.

In the cartridge of the present disclosure, the identification information is provided on the bottom surface of the cup, and at least a portion of the housing accommodating the cup corresponding to the identification information is formed of a transparent member. Therefore, the identification information can be easily read by the reader from the outside of the housing, and the management of the cartridge is facilitated.

### BRIEF DESCRIPTION OF DRAWINGS

FIG. 1 is a perspective view of a printing machine.

FIG. 2 is a top view of the printing machine.

FIG. 3 is a partial external view of a front side of the printing machine.

FIG. 4 is a perspective view of a solder supply device.

FIG. 5 is a partially enlarged view of a holding section of the solder supply device.

FIG. 6 is an external perspective view of a cartridge.

FIG. 7 is a cross-sectional view of the cartridge taken along a plane passing through a central axis and a solder supply air inlet.

FIG. 8 is a diagram illustrating a solder discharge operation using solder supply air.

FIG. 9 is a cross-sectional view of the cartridge taken along a plane passing through the central axis and a solder cutting air inlet.

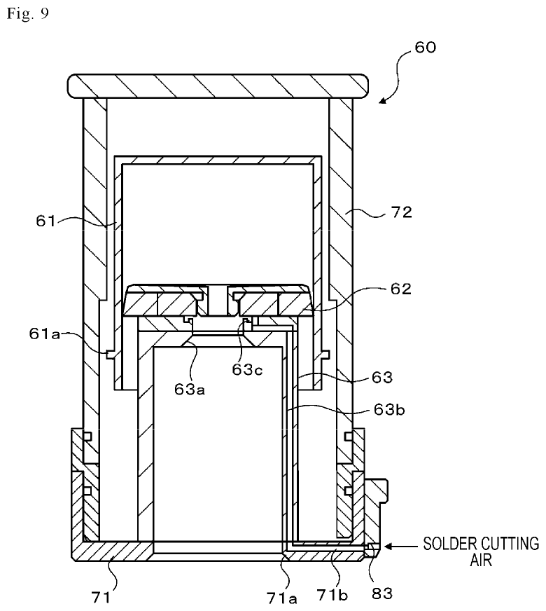

FIG. 10 is a diagram illustrating a solder cutting operation by the solder cutting air.

FIG. 11 is a diagram illustrating an aspect in which an identification code is read.

### DESCRIPTION OF EMBODIMENTS

Hereinafter, an embodiment of the present disclosure will be described with reference to the accompanying drawings.

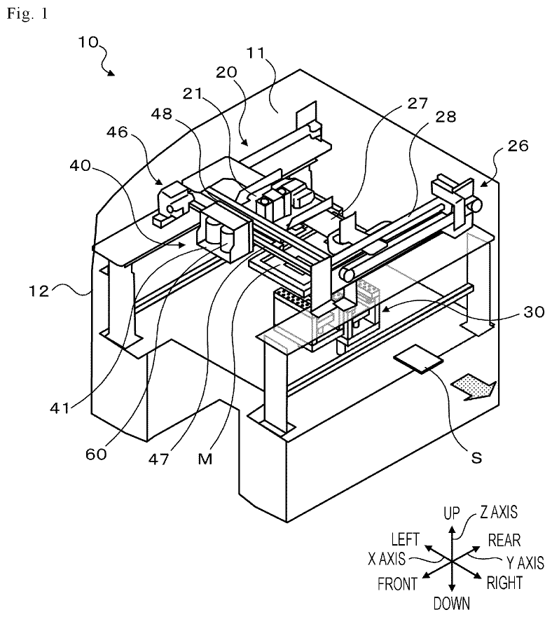

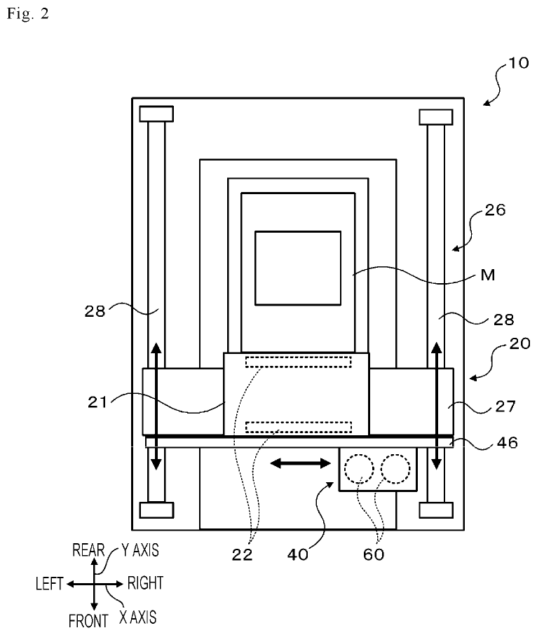

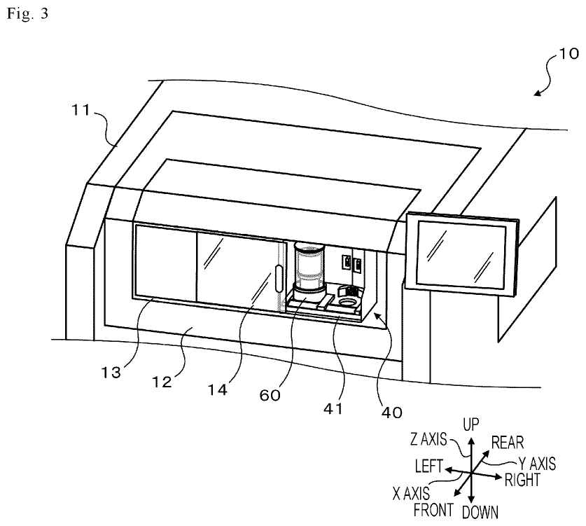

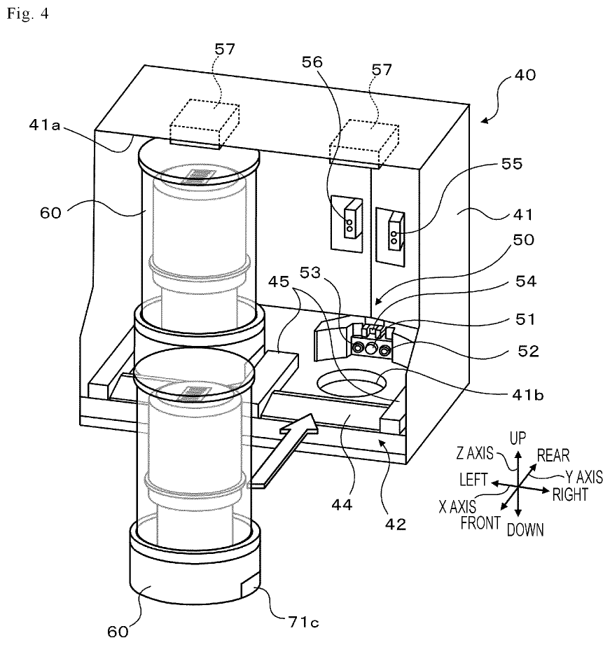

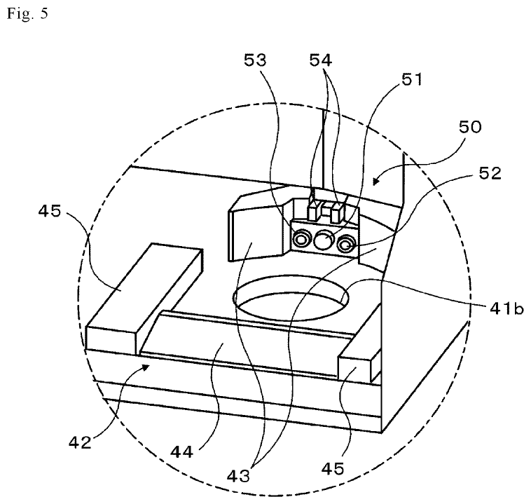

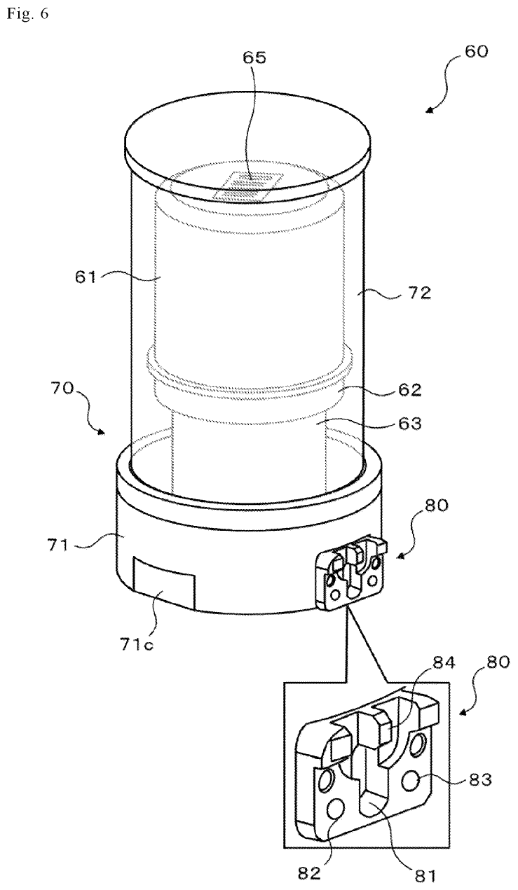

FIG. 1 is a perspective view of printing machine 10. FIG. 2 is a top view of printing machine 10. FIG. 3 is a partial external view of a front side of printing machine 10. FIG. 4 is a perspective view of solder supply device 40. FIG. 5 is a partially enlarged view of holding section 42 of solder supply device 40. FIG. 6 is an external perspective view of cartridge 60. In FIGS. 1 to 4, a left-right direction is referred to as an X axis, a front-rear direction is a Y axis, and an up-down direction is a Z axis.

Printing machine 10 of the present embodiment is a machine that prints solder paste to board S located below screen mask M via pattern holes by using squeegee 22 to press the solder paste on screen mask M into the pattern holes formed in screen mask M. Printing machine 10 constitutes a production line in combination with a component mounter that mounts an electronic component on board S on which solder is printed.

As illustrated in FIG. 1, printing machine 10 includes printing machine main body 11, casing 12 that accommodates printing machine main body 11, and a control device (not illustrated) that controls the entire printing machine. Printing machine main body 11 includes head device 20, board conveyance device 30, and solder supply device 40 as the viscous fluid supply device of the present embodiment.

As illustrated in FIG. 3, window 13 that can be opened and closed by door (sliding door) 14 is provided on a front surface of casing 12.

Head device 20 is installed in an upper portion of printing machine main body 11. As illustrated in FIGS. 1 and 2, head device 20 includes head main body 21 and head moving section 26 that moves head main body 21 in the front-rear direction (Y-axis direction) that is a printing direction. Head moving section 26 includes guide rail 28 extending in the front-rear direction (Y-axis direction), Y-axis slider 27 moving along guide rail 28, and a slider drive section (not illustrated) that drives Y-axis slider 27. As the slider drive section, for example, a slider drive section including a ball screw mechanism and a motor or a slider drive section including a linear motor is used. Head main body 21 includes pair of front and rear squeegees 22 and a squeegee lifting and lowering section (not illustrated) that is configured with, for example, an air cylinder and lifts and lowers corresponding squeegee 22. Pair of squeegees 22 are plate-shaped members that extend in the left-right direction (X-axis direction) orthogonal to the printing direction and are inclined such that pair of squeegees 22 are separated from each other toward the lower side when viewed in the left-right direction.

Board conveyance device 30 is installed in a lower portion of printing machine main body 11. Board conveyance device 30 includes a conveyor device (not illustrated) that conveys board S by a conveyor belt.

Solder supply device 40 holds cylindrical cartridge 60 accommodating solder and supplies the solder from cartridge 60 onto screen mask M. As illustrated in FIG. 1, solder supply device 40 includes holder 41 that detachably holds cartridge 60, and holder moving section 46 that moves holder 41 in the left-right direction (X-axis direction).

Holder moving section 46 includes guide rail 47 provided on Y-axis slider 27 to extend in the left-right direction (X-axis direction), X-axis slider 48 that moves along guide rail 47, and a slider drive section (not illustrated) that drives X-axis slider 48. As the slider drive section, for example, a slider drive section including a ball screw mechanism and a motor or a slider drive section including a linear motor is used. Holder 41 is moved in the front-rear direction and the left-right direction by head moving section 26 and holder moving section 46.

As illustrated in FIG. 4, holder 41 is a box-shaped member in which opening 41a is formed on the front surface and through hole 41b penetrating vertically is formed on the bottom. Door 14 is opened with holder 41 having moved to the front of window 13 of casing 12, so that a worker can attach and detach cartridge 60 to and from holder 41 from the front surface of casing 12 as illustrated in FIG. 3.

As illustrated in FIG. 4, holder 41 is provided with holding section 42, connection-receiving section 50, seating sensor 54, remaining-amount sensors 55 and 56, and reading section 57.

As illustrated in FIGS. 4 and 5, holding section 42 is provided around through hole 41b, and positions and holds cartridge 60 on through hole 41b. In the present embodiment, multiple (two) through holes 41b and holding section 42 are provided in the bottom portion of holder 41 in an arranged manner in the left-right direction, and holder 41 can hold multiple (two) cartridges 60. Accordingly, multiple cartridges 60 accommodating different types of solder are accommodated in holder 41 in advance, so that it is possible to save time and effort for exchanging cartridge 60 when the type of solder to be supplied is switched. Holder 41 may hold only one cartridge 60.

Holding section 42 includes pressing-receiving section 43 provided on the back side of holder 41 with respect to through hole 41b, front guide section 44 provided on the bottom portion of holder 41 and on the front side of holder 41 with respect to through hole 41b, and side guide sections 45 provided on the bottom portion of holder 41 and on both sides of through hole 41b. Pressing-receiving section 43 is a section against which cartridge 60 inserted from opening 41a of holder 41 in the front-rear direction (Y-axis direction) is pressed. In the present embodiment, pressing-receiving sections 43 are provided at two locations, and connection-receiving section 50 is provided between pressing-receiving sections 43. Front guide section 44 is formed in a slope shape rising from the front toward the rear. Side guide sections 45 are band-shaped members extending in the front-rear direction and guide cartridge 60 from both sides. When cartridge 60 is inserted from opening 41a of holder 41 rearward in the front-rear direction, cartridge 60 is pressed against pressing-receiving sections 43 while being guided by side guide sections 45. Cartridge 60 is fitted into a step between the bottom portion of holder 41 and the end of the slope of front guide section 44 while pressed against pressing-receiving sections 43, so that cartridge 60 is positioned by pressing-receiving sections 43, front guide section 44, and side guide sections 45.

As illustrated in FIG. 5, connection-receiving section 50 includes engaging pin 51 protruding forward, solder supply air supply port 52 disposed on a first one of the left and right sides of engaging pin 51, solder cutting air supply port 53 disposed on a second one of the left and right sides of engaging pin 51, and seating sensor 54 that detects seating of cartridge 60. In the present embodiment, seating sensor 54 is configured as an optical sensor including a light projecting section and a light receiving section disposed to face each other at a predetermined interval. Seating sensor 54 may be configured with a proximity sensor or the like.

Remaining-amount sensors 55 and 56 are provided on a back surface portion of holder 41. Remaining-amount sensors 56 and 56 are, for example, an optical sensor, and detect a remaining amount of the solder in cup 61 by detecting a position of cup 61 accommodating the solder. Remaining-amount sensors 56 and 56 are installed at different heights of holder 41. In the present embodiment, remaining-amount sensor 55 is installed at a position slightly lower than remaining-amount sensor 56 so that remaining-amount sensor 55 detects that there is no remaining amount of solder and remaining-amount sensor 56 detects that the remaining amount of solder is small. Remaining-amount sensors 55 and 56 may detect the remaining amount of solder by detecting the weight of cartridge 60.

As illustrated in FIG. 6, cartridge 60 includes cup 61, lid member 62, housing 70, and connection section 80. Cup 61 is a bottomed cylindrical member with an open bottom, and accommodates solder. Identification code 65 (for example, a QR code (registered trademark), a barcode, or the like) for identifying the type of the accommodated solder is attached to the bottom surface of cup 61. Reading section 57 for reading identification code 65 is provided on an upper portion of holder 41 to face identification code 65 attached to the bottom surface of cup 61 in a state where cartridge 60 is mounted on holder 41 (holding section 42).

Lid member 62 is a disk-shaped member that is in sliding contact with the inner peripheral surface of cup 61. The lower surface of lid member 62 is connected to discharge tube 63 having a bottomed cylindrical shape with an open bottom, which has substantially the same height as cup 61. Vertically penetrating through hole 62a is formed in a central portion of lid member 62, and vertically penetrating through hole 63a is formed in a central portion of a bottom surface of discharge tube 63. Lid member 62 and discharge tube 63 are connected to each other such that through holes 62a and 63a communicate with each other.

Housing 70 includes lower housing 71 having a bottomed cylindrical shape with an open top, upper housing 72 having a bottomed cylindrical shape with an open bottom, and coupling member 73 that couples lower housing 71 and upper housing 72 to each other in a state where the openings thereof are abutted against each other. Connection section 80 and width-across-flats section 71c are provided on the outer peripheral surface of lower housing 71. Width-across-flats section 71c is formed to have a width slightly smaller than the width between pair of side guide sections 45, and is formed at a position (phase) where width-across-flats section 71c comes into sliding contact with side guide sections 45 in a state where connection section 80 faces connection-receiving section 50 on the outer peripheral surface of lower housing 71. As a result, the worker can attach cartridge 60 (connection section 80) to holder 41 (connection-receiving section 50) only by aligning the phases so that width-across-flats section 71c is guided by side guide sections 45 and pushing cartridge 60.

Through hole 71a is formed in a central portion of a bottom surface (lower surface) of lower housing 71. The lower end surface of discharge tube 63 is fixed to the bottom surface of lower housing 71 to communicate with through hole 71a. Therefore, the solder in cup 61 is discharged from through hole 62a of lid member 62 to the outside through discharge tube 63 and through hole 71a of lower housing 71.

Housing 70 (lower housing 71 and upper housing 72) is formed such that the inner peripheral surface thereof has a gap in the radial direction with respect to the outer peripheral surface of cup 61 or discharge tube 63. In the present embodiment, upper housing 72 is formed of a transparent member (for example, acrylic or polycarbonate) so that identification code 65 attached to the bottom surface of cup 61 can be read by reading section 57. In upper housing 72, at least a portion corresponding to the bottom surface (upper surface) of cup 61 may be formed of a transparent member.

Connection section 80 includes engaging hole 81, solder supply air inlet 82, solder cutting air inlet 83, and detection piece 84. Engaging hole 81, solder supply air inlet 82, solder cutting air inlet 83, and detection piece 84 are disposed at positions corresponding to engaging pin 51, solder supply air supply port 52, solder cutting air supply port 53, and seating sensor 54, respectively, in a state where connection section 80 and connection-receiving section 50 face each other. When connection section 80 is connected to connection-receiving section 50, engaging pin 51 is engaged with engaging hole 81, and cartridge 60 is mounted (positioned) on holder 41. At the same time, solder supply air supply port 52 is connected to solder supply air inlet 82 to supply solder supply air, and solder cutting air supply port 53 is connected to solder cutting air inlet 83 to supply solder cutting air. Further, since detection piece 84 blocks between the light emitting section and the light receiving section of seating sensor 54 (optical sensor), seating sensor 54 detects that cartridge 60 is seated (mounted). Accordingly, solder supply device 40 can supply the solder from cartridge 60 after checking that cartridge 60 is mounted.

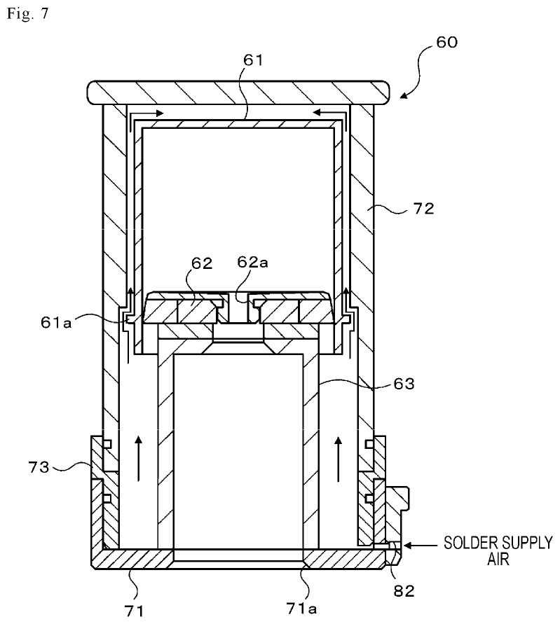

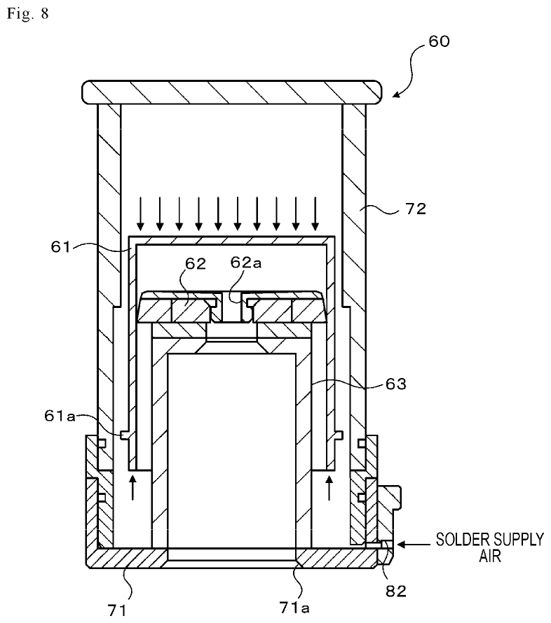

The solder supply air is supplied from solder supply air inlet 82 provided on the side surface of cartridge 60 (lower housing 71). Since there is a gap between the outer peripheral surfaces of discharge tube 63 and cup 61 and the inner peripheral surface of housing 70 (lower housing 71, upper housing 72, and coupling member 73) and between the bottom surface of cup 61 and the bottom surface of upper housing 72, the solder supply air is introduced into these gaps, and a differential pressure is generated due to a pressure-receiving area difference between the opening side and the bottom surface side of cup 61 (see FIG. 7). Accordingly, cup 61 is pushed downward with respect to lid member 62 (see FIG. 8). Then, the solder in cup 61 is discharged to the outside through hole 62a, discharge tube 63, and through hole 71a in this order. Further, the remaining amount of the solder in cup 61 is detected by remaining-amount sensors 55 and 56 in accordance with the position of cup 61.

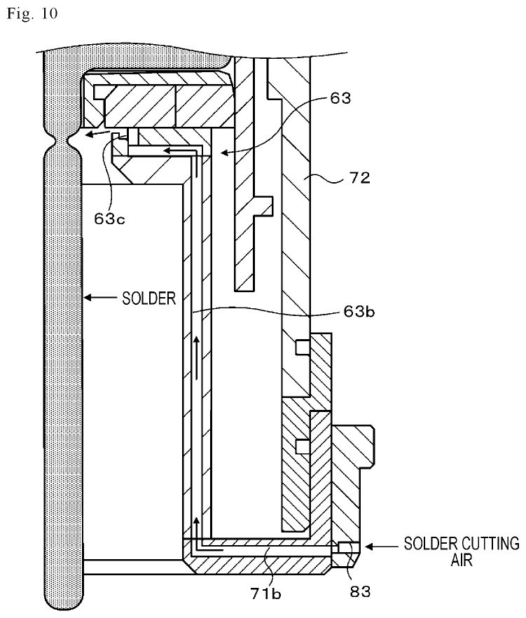

The solder cutting air is supplied from solder cutting air inlet 83 provided on the side surface of cartridge 60 (lower housing 71). Air passages 71b and 63b for solder cutting air are formed in lower housing 71 and discharge tube 63 fixed to lower housing 71. Annular groove 63c is formed in an inner peripheral portion of through hole 63a of discharge tube 63 communicating with through hole 62a of lid member 62. The solder cutting air that has passed through air passages 71b and 63b is supplied to annular groove 63c and discharged radially inward from annular groove 63c. As a result, as illustrated in FIG. 10, the solder hanging down from through hole 62a is cut by the high-pressure air. Therefore, after the solder is supplied from cartridge 60 onto screen mask M, it is possible to prevent the remaining solder from being left in a hanging state and falling to a place different from screen mask M.

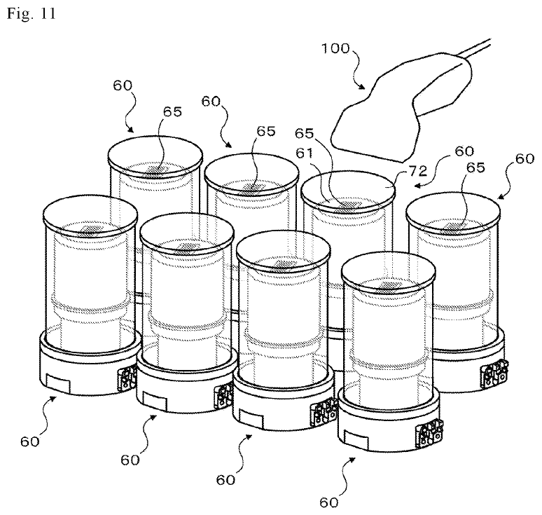

When cartridge 60 is not used, cartridge 60 is accommodated in a state of being accommodated in housing 70 on a shelf or the like of a storage, and when cartridge 60 is used, the worker takes out cartridge 60 from the shelf and mounts cartridge 60 on solder supply device 40 (holder 41) of printing machine 10. As described above, identification code 65 is attached to the bottom surface of cup 61, and upper housing 72 covering cup 61 is formed of a transparent member. Therefore, as illustrated in FIG. 11, even when multiple cartridges 60 are densely arranged on the shelf or the like of the storage, the worker can easily read identification code 65 using code reader 100. As a result, the worker can easily find cartridge 60 accommodating the necessary type of solder when it needs to be used.

Here, a correspondence relationship between elements of the embodiment and elements of the present disclosure described in Claims will be described. That is, solder supply device 40 of the present embodiment corresponds to a viscous fluid supply device of the present disclosure, cartridge 60 corresponds to a cartridge, connection-receiving section 50 corresponds to a mounting-receiving section, holder 41 corresponds to a holder, and solder supply air supply port 52 corresponds to a first air supply section. Cup 61 corresponds to a cup, lid member 62 corresponds to a sliding member, and lower housing 71, upper housing 72, and coupling member 73 correspond to a housing. Solder cutting air supply port 53 corresponds to a second air supply section. Reading section 57 corresponds to a reading section. Side guide section 45 corresponds to a guide section. Seating sensor 54 corresponds to a mounting detection section.

It goes without saying that the present disclosure is not limited to the embodiment described above in any way, and hence can be implemented in various aspects as long as the aspects fall within the technical scope of the present disclosure.

For example, in the above-described embodiment, holder 41 has solder cutting air supply port 53, and cartridge 60 has solder cutting air inlet 83, but these elements may be omitted.

In the above-described embodiment, identification code 65 is attached to the bottom surface of cup 61, and upper housing 72 is formed of a transparent member so that identification code 65 can be read from above housing 70. However, identification code 65 may be attached to the side surface (outer peripheral surface) of cup 61. Identification code 65 may be attached to housing 70.

In the above-described embodiment, the viscous fluid supply device (solder supply device 40) supplies the solder as the viscous fluid to printing machine 10, and printing machine 10 prints the solder on board S as a target. However, the viscous fluid may also be a conductive paste or an adhesive, and the target may be another board such as a three-dimensional object.

In the above-described embodiment, the worker attaches cartridge 60 to holder 41 of solder supply device 40. However, printing machine 10 may include a cartridge storage area for storing multiple cartridges 60 and an automatic exchange device for automatically exchanging cartridge 60 between the cartridge storage area and holder 41. Since cartridge 60 can be attached to holder 41 simply by pressing cartridge 60 rearward in the horizontal direction, the configuration of the automatic exchange device can be further simplified.

As described above, in the viscous fluid supply device of the present disclosure, the cartridge can be attached to the holder and the first air supply section can be connected to the cartridge at the same time simply by pressing the cartridge rearward in the horizontal direction from the opening. As a result, the attachment and detachment of the cartridge can be further facilitated.

In the viscous fluid supply device of the present disclosure, the cartridge may include a bottomed cylindrical cup configured to accommodate the viscous fluid, a sliding member provided to be slidable on an inner peripheral surface of the cup and having a discharge port, and a housing configured to accommodate the cup and the sliding member with a gap on an inner peripheral side, and the first air supply section may supply first air from a side surface of the housing to the gap, and the viscous fluid may be discharged from the discharge port by moving the cup relative to the sliding member by a differential pressure in accordance with a pressure-receiving area difference between a bottom surface side and an opening side of the cup. With this configuration, the device can be made more compact than in a case where the first air is supplied from the upper surface of the housing.

In this case, the viscous fluid supply device may further include a second air supply section provided in the mounting-receiving section and configured to supply second air for cutting the viscous fluid discharged from the discharge port, in which a passage for the second air is formed in the sliding member toward the discharge port. In this way, after the viscous fluid is supplied, the remaining viscous fluid is prevented from being left hanging and from falling to a place different from the supply position.

In these cases, the viscous fluid supply device may further include a reading section configured to read identification information, in which the identification information is provided on a bottom surface of the cup, at least a portion of the housing corresponding to the identification information is formed of a transparent member, and the reading section is disposed such that the bottom surface of the cup is included in a reading range in a state where the cartridge is mounted on the mounting-receiving section. With this configuration, the printing machine can recognize information on the solder by attaching the cartridge to the holder.

In the viscous fluid supply device of the present disclosure, the holder may include a guide section configured to guide horizontal movement of the cartridge. With this configuration, the attachment and detachment of the cartridge can be further facilitated.

The viscous fluid supply device of the present disclosure may further include a mounting detection section provided on the mounting-receiving section and configured to detect whether the cartridge is mounted on the mounting-receiving section. In this way, the cartridge can be more reliably mounted.

In addition, in the viscous fluid supply device of the present disclosure, the holder may be configured such that multiple cartridges are mountable in an arranged manner in a direction that is the horizontal direction and is orthogonal to an insertion and removal direction of the cartridge. With this configuration, multiple cartridges accommodating different types of solder are accommodated in the holder in advance, so that it is possible to save time and effort for exchanging the cartridge even when the type of solder to be supplied is switched.

In the present disclosure, the form of the viscous fluid supply device is adopted, but the form of the cartridge can also be adopted. In the cartridge of the present disclosure, the identification information is provided on the bottom surface of the cup, and at least a portion of the housing accommodating the cup corresponding to the identification information is formed of a transparent member. Therefore, the identification information can be easily read by the reader from the outside of the housing.

### INDUSTRIAL APPLICABILITY

The present disclosure can be used in the manufacturing industry of printing machines and viscous fluid supply devices.

### REFERENCE SIGNS LIST

10: printing machine, 11: printing machine main body, 12: casing, 13: window, 14: door, 20: head device, 21: head main body, 22: squeegee, 26: head moving section, 27: Y-axis slider, 28: guide rail, 30: board conveyance device, 40: solder supply device, 41: holder, 41a: opening, 41b: through hole, 42: holding section, 43: pressing-receiving section, 44: front guide section, 45: side guide section, 46: holder moving section, 47: guide rail, 48: X-axis slider, 50: connection-receiving section, 51: engaging pin, 52: solder supply air supply port, 53: solder cutting air supply port, 54: seating sensor, 55, 56: remaining-amount sensor, 57: reading section, 60: cartridge, 61: cup, 62: lid member, 62a: through hole, 63: discharge tube, 63a: through hole, 63b: air passage, 63c: annular groove, 65: identification code, 70: housing, 71: lower housing, 71a: through hole, 71b: air passage, 71c: width-across-flats section, 72: upper housing, 73: coupling member, 80: connection section, 81: engaging hole, 82: solder supply air inlet, 83: solder cutting air inlet, 84: detection piece, 100: code reader, M: screen mask, S: board.

1. A viscous fluid supply device to be mounted in a printing machine, the viscous fluid supply device being for supplying viscous fluid used for printing, the viscous fluid supply device comprising:
a holder including an opening through which a cartridge accommodating the viscous fluid is insertable and removable, and a mounting-receiving section on which the cartridge is mounted by pressing the cartridge rearward in a horizontal direction from the opening; and
a first air supply section provided on the mounting-receiving section such that the first air supply section is connected to the cartridge in a state where the cartridge is mounted on the mounting-receiving section, and configured to supply first air to the cartridge for discharging the viscous fluid from the cartridge.

2. The viscous fluid supply device according to claim 1,
wherein the cartridge includes a bottomed cylindrical cup configured to accommodate the viscous fluid, a sliding member provided to be slidable on an inner peripheral surface of the cup and having a discharge port, and a housing configured to accommodate the cup and the sliding member with a gap on an inner peripheral side,
the first air supply section supplies the first air from a side surface of the housing to the gap, and
the viscous fluid is discharged from the discharge port by moving the cup relative to the sliding member by a differential pressure in accordance with a pressure-receiving area difference between a bottom surface side and an opening side of the cup.

3. The viscous fluid supply device according to claim 2, further comprising:
a second air supply section provided in the mounting-receiving section and configured to supply second air for cutting the viscous fluid discharged from the discharge port,
wherein a passage for the second air is formed in the sliding member toward the discharge port.

4. The viscous fluid supply device according to claim 2, further comprising:
a reading section configured to read identification information,
wherein the identification information is provided on a bottom surface of the cup,
at least a portion of the housing corresponding to the identification information is formed of a transparent member, and
the reading section is disposed such that the bottom surface of the cup is included in a reading range in a state where the cartridge is mounted on the mounting-receiving section.

5. The viscous fluid supply device according to claim 1, wherein the holder includes a guide section configured to guide horizontal movement of the cartridge.

6. The viscous fluid supply device according to claim 1, further comprising:
a mounting detection section provided on the mounting-receiving section and configured to detect whether the cartridge is mounted on the mounting-receiving section.

7. The viscous fluid supply device according to claim 1, wherein the holder is configured such that multiple of the cartridges are mountable in an arranged manner in a direction that is the horizontal direction and is orthogonal to an insertion and removal direction of the cartridge.

8. A cartridge to be detachably attached to a printing machine, the cartridge being for accommodating viscous fluid used for printing, the cartridge comprising:
a bottomed cylindrical cup configured to accommodate the viscous fluid;
a sliding member provided to be slidable on an inner peripheral surface of the cup and having a discharge port; and
a housing that is a member configured to accommodate the cup and the sliding member with a gap on an inner peripheral side, and has an air inlet for introducing air for discharging the viscous fluid in the cup from the discharge port,
wherein the air inlet is provided on a side surface of the housing,
identification information readable by a reader is provided on a bottom surface of the cup, and
at least a portion of the housing corresponding to the identification information is formed of a transparent member.
